(19) United States
(12) Patent Application Publication
(10) Pub. No.: US 2004/0222422 A1
(43) Pub. Date: Nov. 11, 2004

(54) CMOS inverter layout

(76) Inventors: Wein-Town Sun, Kao-Hsiung (TW); Hu Jen-Yi, Taipei (TW)

Correspondence Address: DUANE MORRIS, LLP, IP DEPARTMENT, ONE LIBERTY PLACE, PHILADELPHIA, PA, 19103-7396, US

(21) Appl. No.: 10/434,296

(22) Filed: May 8, 2003

(51) Int. Cl. H01L 27/108

(52) U.S. Cl. 257/69

(57) ABSTRACT

A CMOS circuit such as an inverter or latch is disclosed where transistors used in the circuit are interconnected using a connector disposed intermediate, and operatively connecting, a gate of a first transistor forming region and a gate of a second transistor forming region, the connector generally defining a Z-shape. It is emphasized that this abstract is provided to comply with the rules requiring an abstract which will allow a searcher or other reader to quickly ascertain the subject matter of the technical disclosure. It is submitted with the understanding that it will not be used to interpret or limit the scope or meaning of the claims.

### FIELD OF INVENTION

The present invention relates to layout of semiconductor devices on a substrate. In particular, the present invention relates to layout of transistor CMOS inverter devices.

### BACKGROUND OF THE INVENTION

Economic layout of semiconductor devices on substrates is important. More efficient layouts lead to a greater number of devices that can be fabricated on a given substrate area.

CMOS devices, e.g. inverters and/or circuits built using inverters, have been fabricated using a substantially U-shaped layout for interconnection. Generally, a thin silicon film is disposed on a substrate that has P-type and N-type regions. Devices fabricated in the P-type and N-type regions are then coupled together in a CMOS configuration where a first portion of circuitry surrounds a further portion of the circuitry. This interconnection is typically in a U-shape.

Although this U-shaped circuit results in a high density of CMOS devices, certain circuits, e.g. latches, are not at their minimum length or width.

### BRIEF DESCRIPTION OF THE DRAWINGS

FIG. 1 is a schematic overview of an exemplary thin film CMOS inverter device; and

FIG. 2 is a schematic overview of an exemplary thin film CMOS latch device.

### DETAILED DESCRIPTION OF THE PREFERRED EMBODIMENT

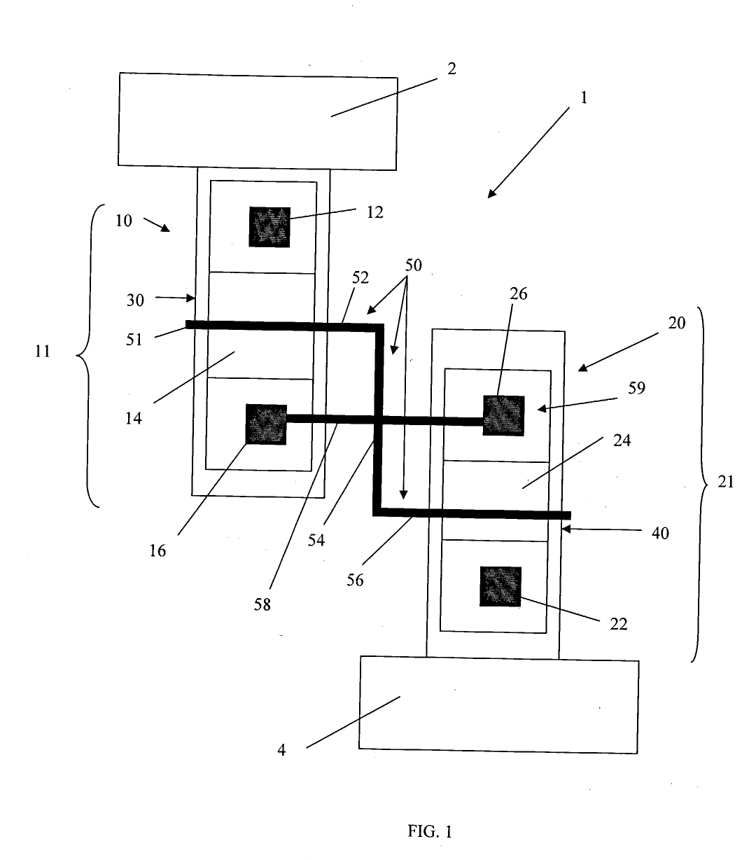

Referring now to FIG. 1, an electronic device, e.g. inverter 1, may be fabricated onto a substrate using methods of fabrication that will be familiar to those of ordinary skill in the semiconductor fabrication arts. In a preferred embodiment, inverter 1 is a thin film CMOS inverter. Inverter 1 comprises first transistor 10, second transistor 20, input 51 which has a generally Z-shaped layout; and output 59. Voltage sources, e.g. V_{DD} 4 and V_{SS} 2, are also shown for reference. In a preferred embodiment, first transistor 10 and second transistor 20 are thin film transistors. As used herein, therefore, the descriptions below apply equally to thin film transistors.

First transistor 10 comprises first gate 14 and first source 12 and may be fabricated in first transistor forming region 11 formed on a semiconductor substrate (not shown in the figures) of a first conductivity type region of the semiconductor substrate. In a preferred embodiment, first transistor forming region 11 may comprise first rectilinear portion 30 extending in a first direction, although the actual geometry of any region herein is not required to be rectilinear. An active device of a first type, e.g. first transistor 10, may be formed using drain region 16 defined in first rectilinear portion 30, gate region 15 defined in first rectilinear portion 30, and source region 13 defined in first rectilinear portion 30. For example, first gate 14 may be fabricated in gate region 15 and first source 12 may be fabricated in source region 13.

Second transistor 20 is disposed proximate first transistor 10. Second transistor 20 comprises second gate 24 and second drain 26 and may be fabricated in second transistor forming region 21 on the semiconductor substrate of a second conductivity type region of the semiconductor substrate. In a preferred embodiment, second transistor forming region 21 may further comprise second rectilinear portion 40 extending in a direction substantially parallel to first rectilinear portion 30. An active device of a second type, e.g. second transistor 20, may be formed from drain region 27 defined in second rectilinear portion 40, gate region 25 defined in second rectilinear portion 40, and source region 22 defined in second rectilinear portion 40.

First transistor 10 and second transistor 20 may be either N-type or P-type devices such as transistors, i.e. NTFT and PTFT devices. In a preferred embodiment, second transistor 20 will be of a type opposite first transistor 10, i.e. P-type when first transistor 10 is N-type.

Input 51, which provides an input for inverter 1, comprises first connector 50. First connector 50 is disposed intermediate, and operatively connects, first gate 14 of first transistor 10 and second gate 24 of second transistor 20. First connector 50 has a generally Z-shape layout geometry that substantially defines a Z-shape comprising first connector leg 52 operatively connected to first gate 14 of first transistor 10 where first connector leg 52 is disposed substantially perpendicular to first transistor 10, second connector leg 56 operatively connected to second gate 24 of second transistor 20 where second connector leg 56 is disposed substantially perpendicular to second transistor 20, and third connector leg 54 which is operatively connected to first connector leg 52 and second connector leg 56. Third connector leg 54 is disposed substantially parallel to and in between first transistor 10 and second transistor 20. However, the generally Z-shaped first connector 50 does not require a diagonal descending member, e.g. third connector leg 54. In a preferred embodiment, a first predetermined portion of first connector leg 52 is disposed on a side of third connector leg 54 opposite the side on which a second predetermined portion of second connector leg 56 is disposed to create the generally Z-shaped geometry.

Output 59 provides an output for inverter 1 and comprises second connector 58 operatively connecting a drain of one transistor to a drain of the other transistor, e.g. first drain 16 of first transistor 10 and second drain 22 of second transistor 20.

In certain embodiments, first gate 14 of first transistor 10 may substantially overlap second gate 24 of second transistor 20. Additionally, first transistor 10 and second transistor 20 may be fabricated onto a substrate substantially in parallel, e.g. side by side or abutting.

In a currently envisioned embodiment, inverter 1 may be fabricated using low-temperature polysilicon (LTPS) transistor (TFT) or polymer organic fabrication techniques, e.g. such as may be used to fabricate polymer organic light emitting displays. Inverter 1 may further be fabricated on a glass or plastic substrate or the like.

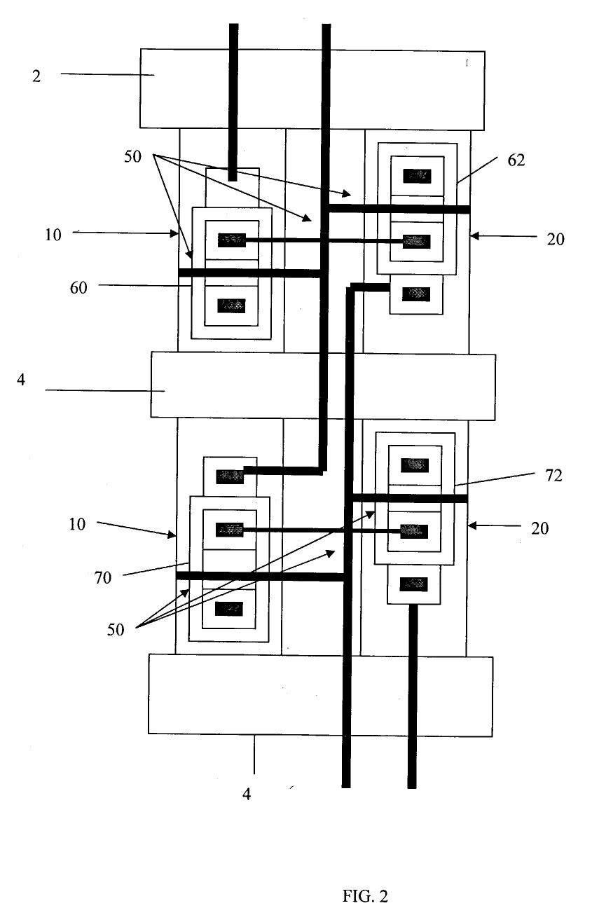

Referring now to FIG. 2, a latch embodiment of the present invention is illustrated. Such latch circuits are well known in the art. Transistor pairs 60,62 and 70,72 are shown interconnected using the generally Z-shaped first connector 50 described above. As used herein, “Z” shape can be generally in the shape of the letter “Z” or its mirror, as described herein above. For example, note that the in the layout illustrated in FIG. 2, Z-shaped first connector 50 is shown as a mirror image of first connector 50 illustrated in FIG. 1.

Typical circuit widths, e.g. for a width to accommodate inverter 1, are around 28 μm for widths of first transistor 10 and second transistor 20 of around 6 μm.

It will be understood that various changes in the details, materials, and arrangements of the parts which have been described and illustrated above in order to explain the nature of this invention may be made by those skilled in the art without departing from the principle and scope of the invention as recited in the appended claims.

We claim:

1. CMOS inverter, comprising:
a. a first transistor comprising a first gate, a first drain, and a first source; and
b. a second transistor comprising a second gate, a second drain, and a second source, the second transistor disposed proximate the first transistor;
c. an input for an inverter, comprising a generally Z-shaped first connector operatively connecting the first gate and the second gate; and
d. an output for the inverter, comprising a second connector operatively connecting the first drain and the second drain.

2. The CMOS inverter of claim 1, wherein:
a. at least one of the first transistor or the second transistor is a thin film transistor.

3. The CMOS inverter of claim 1, wherein:
a. the first transistor is fabricated in a first transistor forming region on a semiconductor substrate of a first conductivity type region of the semiconductor substrate, the first transistor forming region comprising:
i. a first rectilinear portion extending in a first direction;
ii. a drain region defined in the first rectilinear portion;
iii. a gate region defined in the first rectilinear portion; and
iv. a source region defined in the first rectilinear portion;
b. the second transistor is fabricated in a second transistor forming region on the semiconductor substrate of a second conductivity type region of the semiconductor substrate, the second transistor forming region comprising:
i. a second rectilinear portion extending in a direction substantially parallel to the first rectilinear portion in the first direction;
ii. a drain region defined in the second rectilinear portion;
iii. a gate region defined in the second rectilinear portion; and
iv. a source region defined in the second rectilinear portion; and
c. the first connector further comprises:
i. a first connector leg operatively connected to the first gate and disposed substantially perpendicular to the first transistor forming region;
ii. a second connector leg operatively connected to the second gate and disposed substantially perpendicular to the second transistor forming region; and
iii. a third connector leg operatively connected to the first connector leg and the second connector leg and disposed substantially parallel to the first transistor forming region and the second transistor forming region;
d. wherein a first predetermined portion of the first connector leg is disposed on a side of the third connector leg and a second predetermined portion of the second connector leg is disposed on an opposite side of the third connector leg.

4. The CMOS inverter of claim 3, wherein:
a. the first transistor forming region defines at least one of (i) an n-type transistor or (ii) a p-type transistor; and
b. the second transistor forming region defines a transistor of a type opposite the first transistor.

5. The CMOS inverter of claim 3, wherein:
a. the first transistor forming region and the second transistor forming region are fabricated side by side onto a substrate; and
b. the first gate substantially overlaps the second gate.

6. The CMOS inverter of claim 1, wherein:
a. a width of a circuit comprising the first transistor, the second transistor, a voltage source V_{DD}, and a voltage source V_{SS} is around 28 μm for first transistor and second transistor widths of around 6 μm.

7. The CMOS inverter of claim 1, wherein:
a. the CMOS inverter is fabricated using at least one of (i) a low-temperature polysilicon (LTPS) transistor (TFT) fabrication technique or (ii) a polymer (organic) TFT fabrication technique.

8. The CMOS inverter of claim 7, wherein:
a. the CMOS inverter is fabricated on at least one of (i) a glass substrate or (ii) a plastic substrate.
